(19) United States
(12) Patent Application Publication
(10) Pub. No.: US 2026/0056480 A1
(43) Pub. Date: Feb. 26, 2026

(54) SHUTTER APPARATUS FOR A LITHOGRAPHY APPARATUS AND/OR A MASK TEST APPARATUS AND LITHOGRAPHY APPARATUS/MASK TEST APPARATUS

(71) Applicant: Carl Zeiss SMT GmbH, Oberkochen (DE)

(72) Inventor: Johann Irnstetter, Heidenheim an der Brenz (DE)

(21) Appl. No.: 19/306,067

(22) Filed: Aug. 21, 2025

(30) Foreign Application Priority Data
Aug. 22, 2024 (DE) 102024124024.5

(51) Int. Cl. G03F 7/00; G01D 5/20; H02K 21/22

(52) U.S. Cl. CPC G03F 7/70841; G01D 5/20; G03F 7/7055; G03F 7/70825; G03F 7/7085; G03F 7/70891; H02K 21/22

(57) ABSTRACT

A shutter apparatus for a lithography apparatus and/or mask test apparatus, having
a shutter disc mounted rotatably about a rotation axis (A) with at least one opening spaced apart from the rotation axis (A) and serving for transmitting operating light of the lithography apparatus and/or mask test apparatus, and
a magnetic drive and mounting device, with the aid of which the shutter disc is mounted rotatably about the rotation axis (A) and which is configured for rotationally driving the shutter disc about the rotation axis (A), wherein the shutter disc and the drive and mounting device are configured to be arranged within a vacuum housing of the lithography apparatus and/or mask test apparatus.

### CROSS-REFERENCE TO RELATED APPLICATION

This application claims benefit under 35 U.S.C. § 119 to German Patent Application 10 2024 124 024.5, filed on Aug. 22, 2024, the entire content of the above application is incorporated by reference.

### TECHNICAL FIELD

The present invention relates to a shutter apparatus for a lithography apparatus and/or a mask test apparatus, and to a lithography apparatus/mask test apparatus comprising such a shutter apparatus.

### BACKGROUND

Microlithography is used to produce microstructured components, such as for example, integrated circuits. The microlithography process is carried out using a lithography apparatus, which has an illumination system and a projection system. The image of a mask (reticle) illuminated by use of the illumination system is projected by use of the projection system onto a substrate, for example, a silicon wafer, which is coated with a light-sensitive layer (photoresist) and is arranged in the image plane of the projection system, in order to transfer the mask structure to the light-sensitive coating of the substrate.

Driven by the desire for ever smaller structures in the production of integrated circuits, EUV lithography apparatuses which use light at a wavelength in the range of 0.1 nm to 30 nm, in particular 13.5 nm, are currently being developed. Since most materials absorb light at this wavelength, such EUV lithography apparatuses require the use of reflective optical units, i.e., mirrors, instead of refractive optical units, i.e., lens elements, as used previously.

The performance of the lithographic apparatuses used is determined not only by the imaging properties of the projection system but also by an illumination system that illuminates the mask. The illumination system usually contains light sources, which can comprise lasers operated in a pulsed fashion or else plasma sources, and further optical elements, which generate light beams from the light generated by the light source, which converge on the mask at field points. It is desired to adjust and test the generation of the light beams and the resulting beam path in the respective lithographic apparatus prior to the delivery thereof.

In order to test a lithography apparatus or in order to test photomasks that are intended to be imaged using the lithography apparatus, it is desirable to test the entire system or parts thereof prior to the actual start-up and prior to the exposure of wafers with the original light for EUV lithography. Since EUV light sources in particular cannot be switched off and switched on again cost-effectively, controlled blocking of the light in the beam path with the aid of a shutter within the lithography apparatus is therefore necessary.

Known optical or photographic shutters comprise, for example, linearly extending slits which run at high speed past a window through which light can pass. Such slit shutters can be constructed by use of a plurality of movable lamellae. Rotating crescent-shaped discs driven by an electric motor are also known. The high number of mechanical components or the vibrations that arise, for example, as a result of eccentric mounting of the movable components are disadvantageous in this case.

### SUMMARY

Against this background, it is a general aspect of the present invention to provide an improved shutter apparatus for a lithography apparatus and/or mask test apparatus.

In accordance with a first aspect, a shutter apparatus for a lithography apparatus and/or mask test apparatus is proposed. The shutter apparatus has a shutter disc mounted rotatably about a rotation axis with at least one opening spaced apart from the rotation axis and serving for transmitting operating light of the lithography apparatus and/or the mask test apparatus. In addition, the shutter apparatus has a magnetic drive and mounting device, with the aid of which the shutter disc is mounted rotatably about the rotation axis and which is configured for rotationally driving the shutter disc about the rotation axis. Furthermore, the shutter disc and the drive and mounting device are configured to be arranged within a vacuum housing of the lithography apparatus and/or the mask test apparatus.

The operating light of the lithography apparatus and/or the mask test apparatus can be switched off and on with the aid of the shutter apparatus. For example, the lithography apparatus and/or a photomask that is intended to be imaged using the lithography apparatus can thus be tested. This test can be carried out prior to the actual start-up and prior to the exposure of a substrate (e.g., a wafer) with the operating light. By virtue of the use of the shutter apparatus, the operating light, which is also used during operation of the lithography apparatus for imaging a photomask onto a substrate, can also be used in test operation. In particular, in test operation, the operating light in the beam path within the lithography apparatus and/or the mask test apparatus can be blocked in a controlled manner with the aid of the shutter apparatus without a light source (e.g., EUV light source) being switched off and on again, which is possible only with a high outlay.

Mechanical friction such as occurs in the case of a mechanical mounting (e.g., sliding bearing, ball bearing, etc.) is avoided as a result of the magnetic mounting of the shutter disc. As a result, the production of particles is prevented and no lubricant is necessary. Consequently, the service life of the shutter apparatus is significantly lengthened.

Moreover, in the case of the proposed shutter apparatus, the magnetic drive and mounting device provides both the magnetic drive of the shutter disc and the magnetic mounting of the shutter disc. In other words, the magnetic drive and mounting device is a device in which the same components (e.g., the same magnets and magnet coils) provide both the magnetic drive and the magnetic mounting.

The proposed shutter apparatus thus has a greatly simplified configuration by comparison with the prior art. It can thus be produced more simply and more cost-effectively. In addition, the installation space required for the shutter apparatus is significantly reduced by comparison with the prior art.

Arranging the entire magnetic drive and mounting device within the vacuum housing also creates a simpler configuration.

The lithography apparatus (projection exposure apparatus) can be an EUV lithography apparatus. EUV stands for “extreme ultraviolet” and denotes a wavelength of the operating light of between 0.1 nm and 30 nm, in particular 13.5 nm. The lithography apparatus can also be a DUV lithography apparatus. DUV stands for “deep ultraviolet” and denotes a wavelength of the operating light of between 30 nm and 250 nm.

The lithography apparatus comprises an illumination system and a projection system. In a microlithographic method, using the lithography apparatus, the image of a mask (reticle) illuminated by use of the illumination system is projected by use of the projection system onto a substrate, for example, a silicon wafer, which is coated with a light-sensitive layer (photoresist) and arranged in the image plane of the projection system, in order to transfer the mask structure to the light-sensitive coating of the substrate. In this case, the optical unit used can have a reducing imaging scale; by way of example, this optical unit can be embodied with an imaging scale of 1 to 4.

In order to test the lithography apparatus (e.g., the projection optical unit) and/or a mask to be imaged, the lithography apparatus can be modified and can have, e.g., a camera device (in the image plane of the projection system) for capturing the imaged mask. The camera device has, e.g., a charge coupled device (CCD) and/or complementary metal oxide semiconductor (CMOS) image sensor. The modified lithography apparatus comprising the camera device thus makes it possible to test components of the lithography apparatus and/or a mask with original operating light, for example, EUV light of, e.g., 13.5 nm. In this case, the shutter device allows an exposure duration of the camera device to be set in a well-defined manner.

In the case where the lithography apparatus is used for testing masks for lithography, the modified lithography apparatus can also be referred to as a mask test apparatus. The camera device of the modified lithography apparatus or of the mask test apparatus can be used in particular to test masks in the lithography apparatus without the need to scan the masks with the aid of microscopy. In the case where the modified lithography apparatus is a mask test apparatus, the modified lithography apparatus or mask test apparatus can also be equipped with a test optical unit that provides a magnifying imaging scale—instead of with an optical unit that applies a reducing imaging scale for imaging the mask. That is to say that in this embodiment of the modified lithography apparatus or mask test apparatus, the projection optical unit has a magnifying optical unit—instead of a reducing optical unit. Merely by way of example, the magnifying optical unit provides a magnification of approximately 1:250 or 1:500. The mask test apparatus can be used to measure and examine masks with original exposure light with the aid of the camera device provided.

The modified lithography apparatus or mask test apparatus has the vacuum housing and a vacuum pump for evacuating the vacuum housing. The vacuum housing and the vacuum pump are configured in particular to provide and maintain a vacuum in an interior of the vacuum housing. The vacuum provided has a pressure of 10⁻⁷ to 10⁻¹² mbar (hPa), for example. By way of example, both the projection optical unit and the illumination optical unit are arranged within the vacuum housing.

The shutter disc and the drive and mounting device are configured in particular to be arranged completely within the vacuum housing.

A vacuum housing is of importance especially for EUV lithography. Since EUV radiation is absorbed to a great extent in many materials, it is necessary to operate the beam path, that is to say the optical units, masks, reticles, target surfaces such as wafers and the like, in a corresponding lithography apparatus in a vacuum (e.g., ultrahigh vacuum).

The shutter disc of the shutter apparatus is introduced into a beam path of the modified lithography apparatus or the mask test apparatus, for example, within the illumination optical unit.

In the case of the proposed shutter apparatus, reference can also be made to a rotational shutter apparatus or a rotating shutter disc.

The shutter disc is embodied so as to be rotationally symmetrical with respect to the rotation axis, for example.

A rotational shutter apparatus, in particular a rotational shutter apparatus with a rotationally symmetrical shutter disc, has the advantage over slitted shutter devices or rotating discs with non-rotationally symmetrical geometry that a particularly high rotational speed (i.e., high angular frequency) can be realized. Preferably, the shutter disc is driven for rotation with a constant rotational speed. Vibrations of the shutter apparatus can be minimized both by the rotational symmetry and by a constant rotational speed.

The shutter disc has the at least one opening for transmitting the operating light. The at least one opening is arranged spaced apart from the rotation axis. The at least one opening is arranged in particular on a circumferential line around the rotation axis. During the rotation of the disc about the rotation axis and in the case of a beam of the operating light that is incident substantially parallel to the rotation axis, the at least one opening in the shutter disc releases the beam.

The shutter disc has at least one shielding region arranged outside the at least one opening and serving for shielding the operating light. During the rotation of the disc about the rotation axis and in the case of a beam of the operating light that is incident substantially parallel to the rotation axis, the at least one shielding region of the shutter disc blocks the beam (e.g., completely).

The at least one opening is configured in particular for transmitting EUV light (or else DUV light).

The shutter disc preferably comprises a plurality of the at least one opening, wherein the plurality of openings are arranged on the circumferential line around the rotation axis. The plurality of openings are arranged, for example, in a uniformly distributed manner, i.e., at regular distances from one another, on the common circumferential line. Vibrations as a result of the rotation about the rotation axis can be minimized by this regular, e.g., rotationally symmetrical, arrangement of the openings. By way of example, three openings can be provided in each case at an angular distance of 120° with respect to one another on the circumferential line. However, a different number of openings is also possible. Preferably, the openings are provided symmetrically with respect to the rotation axis. Preferably, the center of mass of the shutter disc lies on the rotation axis.

The shutter disc can be formed from a circular disc.

A light source of the lithography apparatus and/or the mask test apparatus generates, e.g., pulsed radiation (e.g., pulsed EUV radiation). That is to say that the operating light incident on the shutter disc is, e.g., pulsed radiation. If the light source generates pulsed radiation with a predetermined pulse duration and pulse frequency, either blocking of the radiation can be effected or the radiation pulses can be passed on in a controlled manner, by use of suitable synchronization of the shutter times of the shutter disc with the pulse duration and pulse frequency of the radiation.

The mounting of the shutter disc is effected in particular exclusively magnetically. That is to say that the shutter disc is mounted in a contactless manner. In particular, the shutter disc is mounted in such a way that it is supported in a freely suspended manner in a magnetic field generated by the magnetic drive and mounting device.

The magnetic mounting of the shutter disc necessitates energization of the magnetic drive and mounting device. A placement bearing and/or emergency bearing can be provided, on which the shutter disc can rest and/or land in the absence of energization of the drive and mounting device. The placement bearing/emergency bearing can comprise, e.g., a sliding bearing and/or rolling bearing, e.g., ball bearing. The sliding bearing comprises, for example, rolling elements (e.g., balls in the case of a ball bearing) and a race, on which the rolling elements run. The rolling elements comprise, for example, plastic, polytetrafluoroethylene (PTFE), polyether ether ketone (PEEK), a polyimide and/or ceramic. The race also comprises, for example, plastic, polytetrafluoroethylene (PTFE), polyether ether ketone (PEEK), a polyimide and/or ceramic. However, the race can also be manufactured from high-grade steel, for example. Rolling elements composed of plastic, polytetrafluoroethylene, polyether ether ketone, polyimide and/or ceramic (and also races composed of these materials) have the advantage of less outgassing and are thus particularly suitable for use in a vacuum. Rolling elements composed of plastic, polytetrafluoroethylene, polyether ether ketone, polyimide and/or ceramic additionally have the advantage that no lubricant is necessary, which is also advantageous for use in a vacuum. Alternatively, the rolling elements and the race can also both be manufactured from high-grade steel and a vacuum-suitable lubricant can be used. A vacuum-suitable lubricant is, for example, a lubricant comprising polytetrafluoroethylene (PTFE) in a binder, e.g., perfluoropolyether (PFPE).

A diameter of the shutter disc is, for example, 500 mm or less, 400 mm or less, 300 mm or less, 200 mm or less, 150 mm or less and/or 100 mm or less.

A height and/or maximum height of the shutter disc is, for example, 100 mm or less, 80 mm or less, 50 mm or less, 30 mm or less and/or 10 mm or less.

A material of the shutter disc comprises, for example, aluminium, an aluminium alloy, high-grade steel and/or titanium.

For use in a vacuum, a surface of the shutter disc is made very smooth, for example. This is because contaminants can settle and/or be adsorbed less easily on a very smooth surface. A surface roughness Ra of the shutter disc has, for example, a value of 1.0 or less, 0.8 or less, 0.5 or less and/or 0.1 or less.

The magnetic drive and mounting device is configured, for example, to drive the shutter disc with a rotational frequency of 15,000 revolutions per minute or more, 50,000 revolutions per minute or more and/or 100,000 revolutions per minute or more.

In accordance with one embodiment, the magnetic drive and mounting device is configured to magnetically mount and drive the shutter disc by use of a magnetic force acting substantially radially on the shutter disc.

As a result, a rotation of the shutter disc and a positionally accurate mounting of the shutter disc can be realized in a simple manner with the aid of the magnetic drive and mounting device. In particular, the arrangement and configuration of the magnetic drive and mounting device in such a way that the shutter disc is driven and mounted by a magnetic force acting substantially radially on the shutter disc makes it possible to set an x-position and a y-position of the shutter disc highly accurately. In this case, the x-position is a position with respect to a first direction (x-direction) arranged perpendicular to the rotation axis, and the y-position is a position with respect to a second direction (y-direction) arranged perpendicular to the first direction and to the rotation axis. Vibrations of the shutter disc can be significantly minimized by the highly accurate positioning and mounting of the shutter disc with respect to its x-and y-positions. In particular, the x-and y-positions of the shutter disc can also be positioned accurately without the need for mechanical balancing.

This is a major advantage over a magnetic drive and/or mounting device in which a magnetic force acts substantially parallel to the rotation axis (e.g., by virtue of magnet coils arranged above magnets with respect to a rotation axis). This is because, in this case, a readjustment, e.g., in the x-and/or y-direction would always also be accompanied by a change in the rotational position with respect to the rotation axis, a change in the rotational position with respect to the y-direction and a change in the position with respect to the direction (z-direction) defined by the rotation axis. This so-called crossover behaviour would generate corresponding undesired vibrations. These vibrations can be prevented by the orientation of the applied magnetic force substantially radially with respect to the shutter disc, as proposed here.

A magnetic force acting substantially radially on the shutter disc is a magnetic force acting substantially perpendicularly to the rotation axis. The radial direction is a radial direction defined with respect to the rotation about the rotation axis.

A magnetic force acting substantially radially on the shutter disc comprises a magnetic force which deviates from an exactly radial direction by ±3° or less, by ±1° or less, by ±0.5° or less, by ±0.1° or less and/or by ±0.05° or less. To compensate external forces such as a gravitational force acting on the shutter disc, the magnetic force comprises in addition to said radial force component also a small axial force component acting parallel to the rotation axis.

In embodiments, the shutter disc has a principal extension plane arranged substantially perpendicular to the rotation axis, and the magnetic drive and mounting device is configured to magnetically mount and drive the shutter disc by use of a magnetic force acting substantially parallel to the principal extension plane.

The principal extension plane of the shutter disc being arranged substantially perpendicular to the rotation axis comprises an arrangement of the principal extension plane exactly perpendicular to the rotation axis and also an arrangement of the principal extension plane which deviates from the exactly perpendicular direction by ±3° or less, by ±1° or less, by ±0.5° or less, by ±0.1° or less and/or by ±0.05° or less.

The magnetic force being arranged substantially parallel to the principal extension plane of the shutter disc comprises an effective direction which deviates from the direction arranged exactly parallel to the principal extension plane by ±3° or less, by ±1° or less, by ±0.5° or less, by ±0.1° or less and/or by ±0.05° or less.

In accordance with a further embodiment, the magnetic drive and mounting device has a plurality of magnets provided on an inner edge of the shutter disc and a plurality of magnet coils spaced apart from the shutter disc with the magnets. Moreover, the magnets and the magnet coils are configured to cooperate in order to provide a magnetic mounting and a magnetic drive of the shutter disc.

The magnets and the magnet coils together form in particular both an electric motor and a magnetic mounting. The magnets and the magnet coils cooperate, e.g., as a kind of linear motor.

The magnets provided on the shutter disc are, for example, magnets secured (e.g., adhesively bonded) to the shutter disc.

The magnets in each case comprise, e.g., neodymium magnets.

By way of example, the magnets can be (e.g., completely) sheathed with nickel (i.e., nickel-plated).

The magnet coils, e.g., each have a wound wire (e.g., copper wire). The wire is wound, e.g., around a core.

A surface of the magnets (e.g., of the nickel-plated magnets) has, for example, a surface roughness Rₐ of 1.0 or less, 0.8 or less, 0.5 or less and/or 0.1 or less. A very smooth surface is advantageous for use in a vacuum, since contaminants can less easily settle thereon.

In the case where the magnet coils do not have a plastic sheathing (i.e., a plastic sheathing in addition to a wire insulation), a surface of the coil cores and/or of the stator can also have, for example, a surface roughness Rₐ of 1.0 or less, 0.8 or less, 0.5 or less and/or 0.1 or less.

A central axis of the magnet coils is in each case preferably oriented radially (with respect to the rotation of the disc).

The magnets and the magnet coils are in particular both configured to be arranged within the vacuum housing.

By virtue of the magnets being arranged on the inner edge of the shutter disc (instead of on an outer edge or in the vicinity of an outer edge of the shutter disc), the magnets cover a smaller area (with respect to a principal extension plane of the disc perpendicular to the rotation axis). Hence an area occupied by the magnet coils is smaller as well. Consequently, the magnetic drive and mounting device can be made more compact and installation space can thus be saved. Moreover, the magnetic drive and mounting device can be manufactured more simply and more cost-effectively. In addition, an outgassing (outgassing rate) of the magnet coils is smaller.

The inner edge of the shutter disc has, e.g., a circular shape. The inner edge of the shutter disc is arranged, e.g., rotationally symmetrically with respect to the rotation axis.

The magnet coils are arranged in particular spaced apart from the magnets. In particular, there is a gap between the magnet coils and the magnets. It can also be stated that a gap is arranged between the shutter disc with the magnets and the stator with the magnet coils. Merely by way of example, the gap has a gap width of 0.5 mm or less, 0.3 mm or less and/or 0.2 mm or less.

In accordance with a further embodiment, the shutter disc forms a rotor of the drive and mounting device, the shutter disc has a central cutout having the rotation axis, and the magnetic drive and mounting device has a stator spaced apart from the shutter disc and arranged within the central cutout.

The central cutout is, for example, a cutout shaped rotationally symmetrically with respect to the rotation axis.

The central cutout is defined, i.e., bounded and/or delimited, by an inner edge of the shutter disc.

The central cutout of the shutter disc is spaced apart and separated in particular from the at least one opening of the shutter disc for transmitting operating light.

The magnetic drive and mounting device has, e.g., a plurality of magnets provided (e.g., secured) on the inner edge of the shutter disc and a plurality of magnet coils arranged on the stator.

The stator with the magnet coils is spaced apart in particular from the shutter disc with the magnets. In the interspace formed therebetween is where a magnetic field of the magnetic drive and mounting device acts.

In accordance with a further embodiment, the stator has a diameter that is 100 mm or less, 80 mm or less, 50 mm or less, 30 mm or less and/or 10 mm or less, and/or the stator has a height that is 100 mm or less, 80 mm or less, 50 mm or less, 30 mm or less and/or 10 mm or less.

The height of the stator can be, for example, one third or less and/or one quarter or less of the diameter of the stator.

The smaller a beam diameter (i.e., beam cross-section) at the location at which the shutter disc is used, the smaller, too, a diameter of the shutter disc can be made. Merely by way of example, the shutter disc is arranged into a beam path between two mirrors of the illumination system. A beam diameter of a beam between the two mirrors tapers, for example, from a first of the two mirrors to an intermediate focus. Moreover, the beam expands again, for example, from the intermediate focus to the second of the two mirrors. The shutter disc is configured, for example, to be arranged in the vicinity of the intermediate focus. Since the beam cross-section is particularly small there, the diameter of the shutter disc can also be particularly small (e.g., 50 mm or less, 30 mm or less and/or 10 mm or less).

In embodiments in which the magnet coils are sheathed by a plastic material (plastic sheathing) (in addition to a wire insulation), the stator with the plastic sheathing can have a diameter that is, e.g., 100 mm or less, 80 mm or less, 50 mm or less, 30 mm or less and/or 10 mm or less. Moreover, in this case, the stator with the plastic sheathing can have a height that is, e.g., 100 mm or less, 80 mm or less, 50 mm or less, 30 mm or less and/or 10 mm or less.

In accordance with a further embodiment:
the magnetic drive and mounting device has a plurality of sensor units for detecting a position of the shutter disc, and/or
the magnetic drive and mounting device has a plurality of sensor units for detecting a rotational position of the shutter disc with respect to a rotation about the rotation axis, an x-position with respect to a first direction arranged perpendicular to the rotation axis, and/or a y-position with respect to a second direction arranged perpendicular to the first direction and to the rotation axis.

A position of the shutter disc can be accurately detected with the aid of the sensor units. A position of the shutter disc can be detected, e.g., once or repeatedly per revolution with the aid of the sensor units.

The plurality of sensor units are arranged in particular on a stator of the magnetic drive and mounting device. The plurality of sensor units are arranged, for example, circumferentially around the stator, e.g., on an outer radius or outer edge of the stator.

The rotational position of the shutter disc with respect to a rotation about the rotation axis has, e.g., a rotation angle (i.e., angle of rotation) of a rotation about the rotation axis. The x-position is in particular a position with respect to the first direction (x-direction). Furthermore, the y-position is in particular a position with respect to the second direction (y-direction).

The sensor units are in particular also arranged within the vacuum housing.

The sensor units can in each case be, e.g., eddy current sensors, capacitive sensors and/or inductive sensors.

In accordance with a further embodiment, the magnetic drive and mounting device has a plurality of magnet coils configured to cooperate with magnets on the shutter disc for the magnetic mounting and for the magnetic drive of the shutter disc. Furthermore, the plurality of magnet coils are each configured as a sensor unit for detecting a position of the shutter disc.

That is to say that the plurality of magnet coils are each configured as an actuator unit for driving the shutter disc and additionally as a sensor unit for detecting a position of the shutter disc.

In this embodiment, what is particularly advantageous is an embodiment of the magnetic drive and mounting device in which the shutter disc is magnetically mounted and driven by a magnetic force acting substantially radially on the shutter disc (i.e., substantially perpendicularly to the rotation axis). For it is by this means that the magnet coils also designed as sensor units can directly and accurately detect the x-and y-positions of the shutter disc. This is not the case for a magnetic force acting substantially parallel to the rotation axis, since magnet coils designed as sensor units can then only expediently measure a z-position with respect to a z-direction arranged parallel to the rotation axis. The x-and y-positions therefore could not be measured directly, but rather could at the very most be determined by back-calculation using the rest of the sensor values.

In accordance with a further embodiment, the shutter apparatus has a closed-loop control device for controlling, on the basis of detected sensor data of a position of the shutter disc, a magnetic drive of the shutter disc and/or a magnetic mounting of the shutter disc in such a way as to control an angular frequency (e.g., also rotational speed) of the shutter disc with respect to a rotation about the rotation axis, to control an x-position of the shutter disc in a first direction perpendicular to the rotation axis, and/or to control a y-position of the shutter disc in a second direction perpendicular to the first direction and to the rotation axis.

The angular frequency (e.g., also rotational speed) of the shutter disc, the x-position of the shutter disc and/or the y-position of the shutter disc can thus be controlled in a feedback closed-loop control.

In particular, an actual angular frequency of the shutter disc can be controlled to a setpoint angular frequency of the shutter disc, an actual x-position of the shutter disc in the first direction (x-direction) can be controlled to a setpoint x-position and/or an actual y-position of the shutter disc in the second direction (y-direction) can be controlled to a setpoint y-position.

The closed-loop control device is, for example, part of a superordinate computing device of the lithography apparatus or the mask test apparatus. The closed-loop control device and/or the superordinate computing device are/is arranged outside the vacuum housing, for example. However, the closed-loop control device and/or the superordinate computing device can also be arranged within the vacuum housing, for example, especially given a suitable sheathing of the respective device in order to avoid outgassing. An arrangement of the closed-loop control device and/or the superordinate computing device with the closed-loop control device within the vacuum housing reduces the complexity of the apparatus, since fewer cables, fewer bushings and the like are necessary.

With the aid of the closed-loop control device, it is thus possible to accurately control an angular frequency (rotational speed) of the shutter disc and a position of the shutter disc with respect to the three degrees of freedom (i.e., a rotation about the z-direction, a translation in the x-direction and a translation in the y-direction). In this case, the remaining three degrees of freedom (i.e., a rotation about the x-direction, a rotation about the y-direction and a translation in the z-direction) are advantageously automatically passively stabilized.

The computing device can also have a trigger control device. By way of example, sensor units for detecting a rotation of the shutter disc and thus a rotational position of the at least one opening can be provided. The trigger control device can be configured, e.g., to generate a trigger signal on the basis of the sensor data. The trigger signal can be used, for example, to activate or control a light source of the lithography apparatus or the mask test apparatus. In particular, the trigger control device can be configured for controlling the light source depending on the trigger signal. For example, the control can be effected in a first mode in such a way that the light source is triggered when the shutter disc releases the beam path for the operating light by use of its at least one opening. In this case, e.g., a camera device of the modified lithography apparatus or the mask test apparatus can be exposed. For example, the control can be effected in a second mode in such a way that the light source is triggered when the shutter disc blocks the beam path by use of its at least one shielding region. In this case, no light is incident, e.g., on a camera device of the modified lithography apparatus or the mask test apparatus.

In accordance with a further embodiment, the closed-loop control device is configured to automatically balance the shutter disc by controlling the x-position and the y-position of the shutter disc.

In accordance with a further embodiment, the magnetic drive and mounting device has at least one acceleration sensor, and the closed-loop control device is configured to balance the shutter disc on the basis of detected data of the at least one acceleration sensor.

The acceleration sensor is configured, for example, to detect oscillations (e.g., vibrations) of the magnetic drive and mounting device. The acceleration sensor is configured, for example, to detect oscillations at least in the x-direction and/or in the y-direction, since the greatest oscillation amplitudes should be expected in these directions. The acceleration sensor can, for example, also be configured to detect oscillations at least in all six degrees of freedom (e.g., if the acceleration sensor comprises a semiconductor element (e.g., a MEMS sensor). The acceleration sensor is arranged and/or mounted on the stator, for example. The acceleration sensor is arranged and/or mounted adjacent to the rotation axis, for example. It is also possible for a plurality of the acceleration sensors described to be provided.

In accordance with a further embodiment, the at least one opening of the shutter disc is embodied as at least one indentation on an outer edge of the shutter disc.

In particular, the at least one opening is not completely bounded (i.e., surrounded) by material of the shutter disc. Rather, the at least one opening is at least one opening that is open in a radial direction that is directed away from the rotation axis.

For example, the shutter disc is formed from a circular disc, on the outer edge of which the at least one opening is formed as at least one recess (e.g., indentation).

In accordance with a further embodiment,
the shutter disc has a plurality of the openings along a circumferential line around the rotation axis and a shielding region of the shutter disc for shielding the operating light is arranged between each two adjacent openings from among the plurality of openings along the circumferential line, and
the shielding region has a rounded corner as viewed in a plan view parallel to the rotation axis, and/or
the operating light has a beam cross-section shape at the location of the shutter disc and a shape of the respective shielding region as viewed in a plan view parallel to the rotation axis is embodied in such a way that the respective shielding region shields exclusively the beam cross-section shape and a tolerance region around the beam cross-section shape.

By virtue of the rounded corner and/or by virtue of the respective shielding region shielding exclusively the beam cross-section shape and the tolerance region around the beam cross-section shape, the shutter disc can be produced with as little material as possible. A mass and thus a rotational energy of the shutter disc can thus be kept as small as possible.

The respective shielding region shielding exclusively the beam cross-section shape and the tolerance region around the beam cross-section shape means in particular that a region outside the beam cross-section shape with the tolerance region is not shielded by the shutter disc (i.e., not in any rotational position).

By way of example, the shutter disc has a plurality of the openings arranged on a circumferential line around the rotation axis. By way of example, the shutter disc has a shielding region between each two adjacent openings. Furthermore, the shutter disc has, e.g., an inner ring portion (on which, e.g., the magnets are provided) connected to the plurality of shielding regions via corresponding bridges.

The beam cross-section shape is circular, for example. However, the beam cross-section shape can also comprise an elliptic, superelliptic or otherwise shaped beam cross-section shape.

In accordance with a further embodiment,
the magnetic drive and mounting device has a plurality of magnet coils configured to cooperate with magnets on the shutter disc for the magnetic mounting and for the magnetic drive of the shutter disc, and
the magnet coils each have a metal core, or
the magnet coils each have a plastic core.

The metal core comprises, for example, a ferromagnetic metal core, e.g., iron (iron core). However, the metal core can, for example, also comprise a non-ferromagnetic metal core, e.g., composed of aluminium, copper, titanium and/or a high-grade steel alloy.

The magnetic flux can be improved with the aid of a ferromagnetic metal core (e.g., iron core). The respective metal core (e.g., iron core) can have, e.g., a multiplicity of metal sheets (e.g., iron sheets) in order to minimize remagnetization losses. Heat dissipation can be provided with the aid of a ferromagnetic and/or non-ferromagnetic metal core.

Remagnetization losses can be reduced to an even greater extent with the aid of a plastic core (in particular instead of a metal core). In addition, heat generation can be reduced. Especially if the shutter disc is made small (e.g., diameter of less than 15 cm) and thus lightweight and hence only a small drive force is necessary for driving the shutter disc, a plastic core is particularly advantageous.

A material of the plastic core comprises, e.g., an epoxy resin and/or polyurethane (PUR).

In accordance with a further embodiment, the magnetic drive and mounting device has a plurality of magnet coils configured to cooperate with magnets on the shutter disc for the magnetic mounting and for the magnetic drive of the shutter disc. Furthermore, the magnet coils each have a wire winding with a wire sheathed with an insulating material. The insulating material comprises polytetrafluoroethylene, polyether ether ketone and/or a polyimide.

Owing to its low outgassing, an insulating material comprising polytetrafluoroethylene, polyether ether ketone and/or a polyimide is particularly well suited to use in a vacuum.

The wire of the magnet coils is, e.g., a copper wire.

In accordance with a further embodiment, the magnetic drive and mounting device has a plurality of magnet coils configured to cooperate with magnets on the shutter disc for the magnetic mounting and for the magnetic drive of the shutter disc. Moreover, the magnet coils are sheathed with a plastic material.

The sheathing with the plastic material can be provided in particular in addition to the wire insulation mentioned above.

Outgassing can be reduced and/or prevented by the plastic material. Contamination and/or disturbance of the vacuum in the vacuum chamber can thus be prevented.

The magnet coils can be sheathed with the plastic material in each case individually or else jointly. By way of example, the stator with the magnet coils (and, e.g., coil cores) as a whole can also be sheathed with the plastic material.

The plastic material with which the magnet coils are sheathed comprises, for example, an epoxy resin and/or polyurethane (PUR).

A closed-loop control device and/or a superordinate computing device having the closed-loop control device can also be sheathed with a plastic material. In this case, the closed-loop control device and/or the computing device with the closed-loop control device can also be arranged within the vacuum housing—without producing problems as a result of outgassing.

The plastic material (e.g., the potting compound) can optionally be coated, for example, with (non-ferromagnetic) metal in order to reduce outgassing of the plastic. A possible coating is, e.g., a nickel and/or chromium coating. Alternatively, a corresponding moulded part can be arranged over the plastic material. Especially in the case of sheathing of a closed-loop control device and/or a superordinate computing device having the closed-loop control device with a plastic material, the aforementioned moulded part can be employed for reducing outgassing of the plastic.

In accordance with a further embodiment, the shutter apparatus has a cooling apparatus for cooling the magnetic drive and mounting device. Furthermore, the cooling apparatus has:
a cooling ring arranged around the shutter disc and serving for dissipating heat, and/or
a cooling housing arranged around the shutter disc and serving for dissipating heat, and/or
a cooling pipe with a capillary structure and a working liquid accommodated in the interior of the cooling pipe, wherein the cooling pipe connects a space around the shutter disc to an exterior space.

By use of the cooling ring and/or the cooling housing arranged around the shutter disc, it is also possible to hold back particles (e.g., in the case of a malfunction of the drive and mounting device). The cooling ring is, for example, a cooling housing having only two openings accordingly for the operating light radiated in and the operating light radiated out.

Heat emission from the magnet coils and/or the shutter disc can be reduced by use of the cooling ring and/or the cooling housing.

An inner wall of the cooling ring and/or of the cooling housing provides, e.g., the highest possible absorption or emissivity of thermal radiation. By way of example, said inner wall has a nickel-phosphorus coating (NiP coating) or else some other coating having a high absorption or emissivity of thermal radiation.

An outer wall of the cooling ring and/or of the cooling housing provides, e.g., a low emissivity of thermal radiation. By way of example, said outer wall comprises a polished and/or lustrous metal.

A basic material of the cooling ring and/or of the cooling housing has, e.g., a high thermal conductivity in order to guide the heat rapidly in the direction of the outer wall.

The cooling pipe connects a space around the shutter disc to an exterior space. The exterior space is, e.g., a space outside the vacuum housing. In this case, the cooling pipe is configured to dissipate heat from the space around the shutter disc to the exterior space outside the vacuum housing.

Optionally, e.g., cooling fins and/or an exterior water cooling facility can be provided at an end of the cooling pipe arranged in the exterior space (i.e., at atmospheric pressure).

The shutter apparatus can thus be cooled.

Especially with a shutter disc of low mass and thus with a low drive energy, a water cooling facility such as is conventionally used is not required. Rather, a cooling device having one or more of the proposed cooling ring, cooling housing and/or capillary cooling pipe is sufficient.

The cooling ring and/or the cooling housing comprise(s), e.g., aluminium. The cooling ring and/or the cooling housing comprise(s) in particular no iron that would disturb the magnetic properties of the drive and mounting device.

The cooling housing is, e.g., a closed cooling housing.

In accordance with a second aspect, a lithography apparatus and/or a mask test apparatus are/is proposed. The lithography apparatus and/or the mask test apparatus comprise(s) a shutter apparatus as described above and a vacuum housing for providing a vacuum, wherein the shutter disc and the drive and mounting device of the shutter apparatus are arranged within the vacuum housing.

The shutter disc and the drive and mounting device of the shutter apparatus are arranged in particular completely within the vacuum housing.

The shutter apparatus, in particular the shutter disc and the drive and mounting device, is preferably used in an illumination optical unit of the projection exposure apparatus. However, the shutter apparatus, in particular the shutter disc and the drive and mounting device, can also be used in a projection optical unit. In the case of use in a projection optical unit, the radiation cross-section to be shielded or released is smaller. Thus, in the case of use in a projection optical unit, more openings can be arranged on the shutter disc, as a result of which a required rotational speed is lower. Alternatively, the shutter disc can be made smaller in the case of use in a projection optical unit.

The respective unit described above or below, for example, the computing apparatus, the closed-loop control device, the first and second controller units and the trigger control device, can be implemented in terms of hardware technology and/or in terms of software technology. In the case of an implementation in terms of hardware technology, the respective unit can be embodied as an apparatus or as part of an apparatus, for example as a computer or as a microprocessor. In the case of an implementation in terms of software technology, the respective unit can be embodied as a computer program product, as a function, as a routine, as part of a program code or as an executable object.

“A(n); one” in the present case should not necessarily be understood as restrictive to exactly one element. Rather, a plurality of elements, such as for example, two, three or more, can also be provided. Nor should any other numeral used here be understood to the effect that there is a restriction to exactly the stated number of elements. Rather, unless indicated otherwise, numerical deviations upwards and downwards are possible.

The embodiments and features described for the shutter apparatus apply, mutatis mutandis, to the proposed lithography apparatus and/or mask test apparatus, and vice versa.

Further possible implementations of the invention also encompass not explicitly mentioned combinations of features or embodiments that are described above or hereinafter with respect to the exemplary embodiments. A person skilled in the art will also add individual aspects as improvements or supplementations to the respective basic form of the invention.

Further advantageous configurations and aspects of the invention are the subject matter of the dependent claims and also of the exemplary embodiments of the invention that are described below. The invention is explained in greater detail hereinafter on the basis of preferred embodiments with reference to the appended figures.

### BRIEF DESCRIPTION OF DRAWINGS

FIG. 1 shows a schematic meridional section of a projection exposure apparatus for EUV projection lithography in accordance with one embodiment;

FIG. 2 shows a schematic cross-sectional view of a shutter apparatus of the projection exposure apparatus from FIG. 1 in accordance with one embodiment;

FIG. 3 shows a plan view of a shutter disc of the shutter apparatus from FIG. 2;

FIG. 4 shows magnet coils—sheathed with a plastic material—of the shutter apparatus from FIG. 2 in accordance with one embodiment;

FIG. 4A shows magnet coils of the shutter apparatus from FIG. 2 in accordance with one embodiment;

FIG. 4B shows a view similar to FIG. 4, depicting dimensions of the magnet coils in accordance with one embodiment;

FIG. 5 shows a view similar to FIG. 3, showing sensor units of the shutter apparatus in accordance with one embodiment;

FIG. 6 shows a closed-loop control circuit for controlling a magnetic drive and a magnetic mounting of the shutter disc from FIG. 2 in accordance with one embodiment; and

FIG. 7 shows a number of variants of a cooling apparatus of the shutter apparatus from FIG. 2 in accordance with one embodiment.

### DETAILED DESCRIPTION

In the figures, identical or functionally identical elements have been provided with the same reference signs, unless indicated otherwise. Furthermore, it should be noted that the illustrations in the figures are not necessarily true to scale.

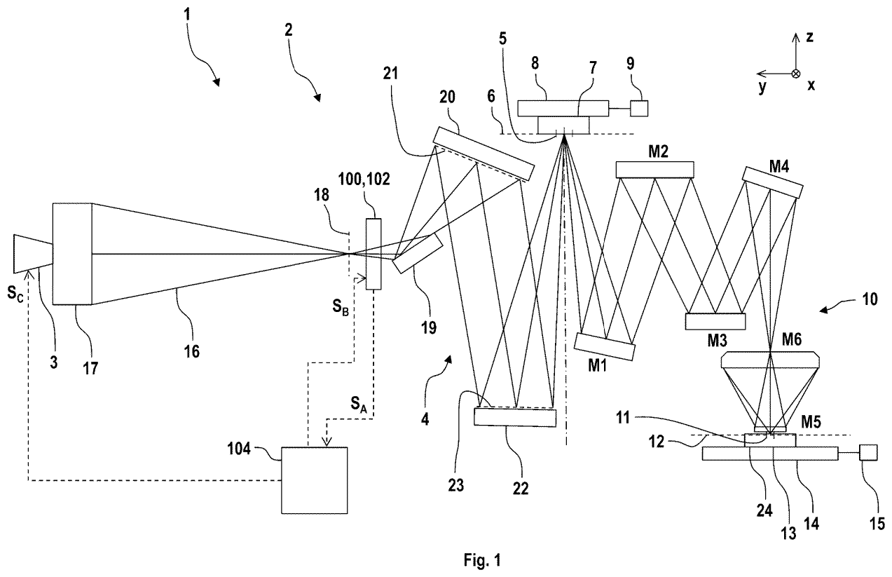

FIG. 1 shows an embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, in particular in a scanning direction.

FIG. 1 depicts, for explanation purposes, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs along the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6.

Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular along the y-direction y. The displacement, firstly, of the reticle 7 by way of the reticle displacement drive 9 and, secondly, of the wafer 13 by way of the wafer displacement drive 15 can be implemented so as to be synchronized with one another.

The light source 3 is an EUV radiation source. The light source 3 emits in particular EUV radiation 16, which is also referred to below as used radiation, illumination radiation or illumination light. The used radiation 16 has in particular a wavelength in the range of between 5 nm and 30 nm. The light source 3 can be a plasma source, for example, an LPP (short for: laser produced plasma) source or a DPP (short for: gas-discharge produced plasma) source. It can also be a synchrotron-based radiation source. The light source 3 can be an FEL (short for: free-electron laser).

The illumination radiation 16 emanating from the light source 3 is focused by a collector 17. The collector 17 can be a collector having one or more ellipsoidal and/or hyperboloidal reflection surfaces. The at least one reflection surface of the collector 17 can be impinged upon by the illumination radiation 16 with grazing incidence (abbreviated as: GI), that is to say with angles of incidence greater than 45°, or with normal incidence (abbreviated as: NI), that is to say with angles of incidence less than 45°. The collector 17 can be structured and/or coated firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optical unit 4.

The illumination optical unit 4 comprises a deflection mirror 19 and, disposed downstream thereof in the beam path, a first facet mirror 20. The deflection mirror 19 can be a plane deflection mirror or alternatively a mirror with a beam-influencing effect going beyond the pure deflection effect. Alternatively or additionally, the deflection mirror 19 can be embodied as a spectral filter separating a used light wavelength of the illumination radiation 16 from extraneous light having a wavelength that deviates therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which may also be referred to as field facets. Only some of these first facets 21 are illustrated in FIG. 1 by way of example.

The first facets 21 can be embodied as macroscopic facets, in particular as rectangular facets or as facets with an arcuate or partly circular edge contour. The first facets 21 can be embodied as plane facets or alternatively as facets with convex or concave curvature.

As is known, for example, from DE 10 2008 009 600 A1, the first facets 21 themselves can also be composed in each case of a multiplicity of individual mirrors, in particular a multiplicity of micromirrors. The first facet mirror 20 can be embodied in particular as a microelectromechanical system (MEMS system). For details, reference is made to DE 10 2008 009 600 A1.

The illumination radiation 16 travels horizontally, i.e., along the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror.

The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal boundary, or can alternatively be facets composed of micromirrors. In this regard, reference is likewise made to DE 10 2008 009 600 A1.

The second facets 23 can have plane or alternatively convexly or concavely curved reflection surfaces.

The illumination optical unit 4 thus forms a doubly faceted system. This fundamental principle is also referred to as a fly's eye condenser (or fly's eye integrator).

It can be advantageous to arrange the second facet mirror 22 not exactly in a plane that is optically conjugate to a pupil plane of the projection optical unit 10. In particular, the second facet mirror 22 can be arranged so as to be tilted in relation to a pupil plane of the projection optical unit 10, as described, for example, in DE 10 2017 220 586 A1.

The individual first facets 21 are imaged into the object field 5 with the aid of the second facet mirror 22. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 can be arranged in the beam path between the second facet mirror 22 and the object field 5. The transfer optical unit can have exactly one mirror or alternatively two or more mirrors, which are arranged one behind another in the beam path of the illumination optical unit 4. The transfer optical unit can in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20 and the second facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 by use of the second facets 23 or using the second facets 23 and a transfer optical unit is regularly only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve, or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6 and, for example, can be 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

The projection optical unit 10 can be embodied in particular in anamorphic fashion. It has in particular different imaging scales βx, βy in the x- and y-directions x, y. The two imaging scales βx, βy of the projection optical unit 10 are preferably (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e., in a direction perpendicular to the scanning direction.

The projection optical unit 10 leads to a reduction in size of 8:1 in the y-direction y, i.e., in the scanning direction.

Other imaging scales are likewise possible. Imaging scales with the same sign and the same absolute value in the x-direction x and y-direction y are also possible, for example, with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x-direction x and y-direction y are known from US 2018/0074303 A1.

In each case one of the second facets 23 is assigned to exactly one of the first facets 21 for forming a respective illumination channel for illuminating the object field 5. In particular, this can result in illumination according to the Köhler principle. The far field is decomposed into a multiplicity of object fields 5 with the aid of the first facets 21. The first facets 21 generate a plurality of images of the intermediate focus on the second facets 23 respectively assigned to them.

The first facets 21 are each imaged onto the reticle 7 by an assigned second facet 23 with images overlaid over one another for the purpose of illuminating the object field 5. The illumination of the object field 5 is in particular as homogeneous as possible. It preferably has a uniformity error of less than 2%. Field uniformity can be attained by overlaying different illumination channels.

The illumination of the entrance pupil of the projection optical unit 10 can be defined geometrically by an arrangement of the second facets 23. The intensity distribution in the entrance pupil of the projection optical unit 10 can be set by selection of the illumination channels, in particular the subset of the second facets 23 that guide light. This intensity distribution is also referred to as illumination setting or illumination pupil filling.

A likewise preferred pupil uniformity in the region of portions of an illumination pupil of the illumination optical unit 4 that are illuminated in a defined manner can be attained by a redistribution of the illumination channels.

Further aspects and details of the illumination of the object field 5 and, in particular, of the entrance pupil of the projection optical unit 10 are described below.

In particular, the projection optical unit 10 can comprise a homocentric entrance pupil. The latter can be accessible. It can also be inaccessible.

The entrance pupil of the projection optical unit 10 regularly cannot be exactly illuminated with the second facet mirror 22. In the case of imaging by the projection optical unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area constitutes the entrance pupil or an area conjugate thereto in real space. In particular, this area exhibits a finite curvature.

It may be the case that the projection optical unit 10 has different positions of the entrance pupil for the tangential beam path and for the sagittal beam path. In this case, an imaging element, in particular an optical component of the transfer optical unit, should be provided between the second facet mirror 22 and the reticle 7. With the aid of this optical element, the different position of the tangential entrance pupil and of the sagittal entrance pupil can be taken into account.

In the arrangement of the components of the illumination optical unit 4 illustrated in FIG. 1, the second facet mirror 22 is arranged in an area conjugate to the entrance pupil of the projection optical unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

In order to test the radiation source 3, the mask 13 or the imaging performance of the projection optical unit 10, for example, a camera device 24 can be provided instead of a wafer 13. In other words, the element identified by the two reference signs 13 and 24 in FIG. 1 can be either a wafer 13 (in lithographic operation of the lithography apparatus 1) or a camera device 24 (in test operation of the lithography apparatus 1). Moreover, a shutter apparatus 100 is provided in order to control an exposure in test operation. The shutter apparatus 100 has a shutter device 102 arranged in the beam path of the operating light 16 in the illumination system 4.

Furthermore, the shutter apparatus 100 has a computing device 104, which can be program-controlled, for example. The computing device 104 is communicatively coupled to the shutter device 102. The computing device 104 receives in particular sensor data S_{A} from the shutter device 102 and transmits control signals S_{B} to the shutter device 102. In addition, the computing device 104 transmits control signals S_{C} to the radiation source 3. By way of example, the computing device 104 can control the radiation source 3 in order to activate laser pulses for plasma discharge. The computing device 104 furthermore controls, for example, the shutter device 102 and the radiation source 3 in such a way that the camera device 24 is exposed with operating light 16 after the latter has passed through the projection optical unit 10.

The exposure of coated semiconductor wafers involves a generally reducing imaging of the mask structures of the mask 5 by the projection optical unit 10. In a modified embodiment of the lithography apparatus 1 (e.g. as a mask test apparatus), the masks 5 used in wafer production can be tested and measured. In an implementation of the lithography apparatus 1 as a measuring and test apparatus for testing the light source 3, the mask 5 and/or the optical elements of the projection optical unit 10, use is made of an optical arrangement (not shown) that provides a magnifying imaging (e.g., on a scale of 1:250 or 1:500) of the mask structures of the mask 5 to the camera device 24. In order to set a suitable exposure time for the camera device 24, the shutter device 102 is controlled accordingly. This is to say that in a modified lithography apparatus 1 for testing and/or a mask test apparatus 1, the camera device 24 (e.g., CCD and/or CMOS) is arranged instead of the wafer 13. Moreover, the collector 17 can also be omitted, since even without the collector 17 a quantity of light can be sufficient for operation as a test apparatus. Furthermore, in a modified lithography apparatus 1 for testing and/or a mask test apparatus 1, the facet mirrors 20, 22 and their different deflections can be simulated just by way of two stops in the region of the reticle 7 (incoming beam path and outgoing beam path to the reticle 7). In this case, different facet mirror settings can be simulated using different stops.

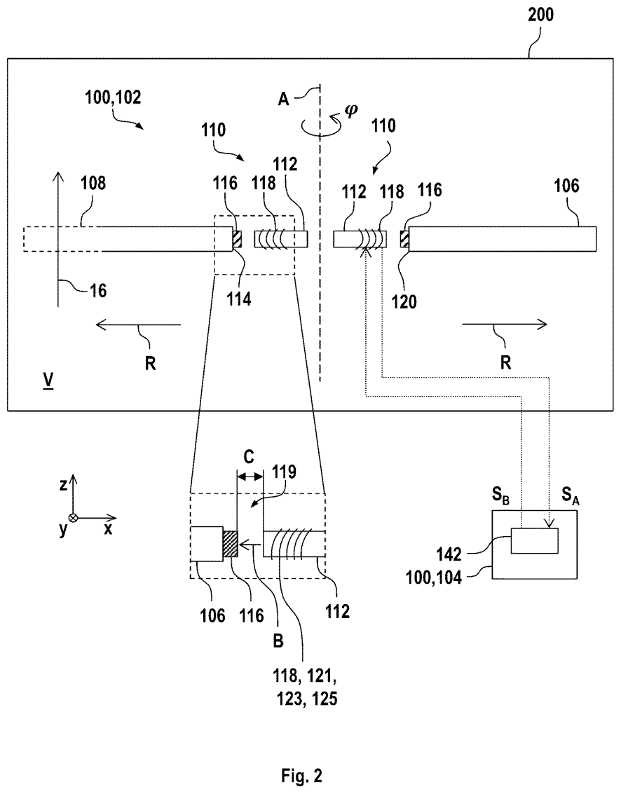

The illumination system 4, the projection system 10 and the shutter device 102 are arranged in particular within a vacuum housing 200 of the modified lithography apparatus 1 and/or the mask test apparatus 1 (not shown in FIG. 1, only shown in FIG. 2). A vacuum V (e.g., ultrahigh vacuum) prevails within the vacuum housing 200.

FIG. 2 shows a schematic cross-sectional illustration of one exemplary embodiment of a shutter apparatus 100 comprising a shutter device 102 and a computing device 104.

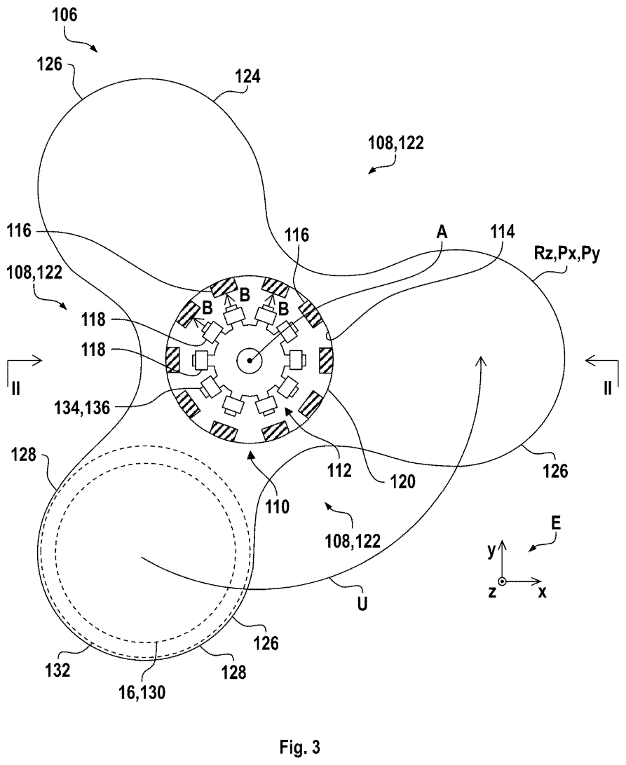

As can be seen in FIG. 2, the shutter apparatus 100, in particular the shutter device 102, has a shutter disc 106 mounted rotatably (rotation angle ℠) about a rotation axis A. The shutter disc 106 has at least one opening 108 spaced apart from the rotation axis A and serving for transmitting operating light 16 of the modified lithography apparatus 1 and/or the mask test apparatus. FIG. 3 reveals a plan view of the shutter disc 106 from FIG. 2 (with respect to the shutter disc 106 and a drive and mounting device 110, FIG. 2 is a cross-section along line II-II in FIG. 3). In the example shown in FIGS. 2 and 3, the shutter disc 106 has three openings 108 arranged along a circumferential line U around the rotation axis A and serving for transmitting operating light 16. In other examples, however, a different number of openings 108 can also be provided.

The shutter apparatus 100, in particular the shutter device 102, additionally has a magnetic drive and mounting device 110. With the aid of the magnetic drive and mounting device 110, the shutter disc 106 is mounted rotatably about the rotation axis A. That is to say that, with the aid of the magnetic drive and mounting device 110, the shutter disc 106 is mounted and positioned purely magnetically and in particular in a contactless manner. Furthermore, the magnetic drive and mounting device 110 is configured to drive the shutter disc 106 for rotation about the rotation axis A with a predetermined angular frequency ω (ω=dφ/dt).

FIG. 2 shows a vacuum housing 200 of the lithography apparatus 1 and/or the mask test apparatus, the shutter device 102 with the shutter disc 106 and the drive and mounting device 110 being arranged completely in said housing. As a result, the shutter device 102 can be realized particularly compactly and easily.

The shutter disc 106 forms in particular a rotor of the magnetic drive and mounting device 110. Moreover, the magnetic drive and mounting device 110 has a stator 112, as can be seen in FIG. 2.

The magnetic drive and mounting device 110 has a plurality of magnets 116 arranged on an inner edge 114 of the shutter disc 106. For reasons of clarity, only some of the magnets 116 are provided with a reference sign in the figures. The magnets 116 are secured, for example, to the inner edge 114 of the shutter disc 106 (e.g., adhesively bonded thereto or secured thereto in some other way).

The magnets 116 can be arranged, e.g., along a second circumferential line around the rotation axis A, which is arranged closer to the rotation axis A than the circumferential line U on which the at least one opening 108 is arranged.

The magnetic drive and mounting device 110 additionally has a plurality of magnet coils 118, which cooperate with the magnets 116 in order to provide the magnetic mounting and the magnetic drive. For reasons of clarity, only some of the magnet coils 118 are provided with a reference sign in the figures.

In particular, the magnet coils 118 are arranged spaced apart from the magnets 116 (i.e., with no physical contact). In particular, there is a gap 119 having a gap width C between the magnet coils 118 and the magnets 116. It can also be stated that a gap 119 is arranged between the shutter disc 106 with the magnets 116 and the stator 112 with the magnet coils 118. Merely by way of example, the gap 119 has a gap width C of 0.5 mm or less, 0.3 mm or less and/or 0.2 mm or less.

The shutter disc 106 has in particular a central cutout 120, within which the stator 112 with the magnet coils 118 is arranged. The magnet coils 118 can be arranged, e.g., along a third circumferential line around the rotation axis A, which is arranged closer to the rotation axis A than the circumferential line U on which the at least one opening 108 is arranged, and than the second circumferential line, on which the magnets 116 are arranged.

As can be seen in the enlarged detail in FIG. 2, the magnetic drive and mounting device 110 is configured to magnetically mount and drive the shutter disc 106 by use of a magnetic force B acting substantially radially (radial direction R in FIG. 2) on the shutter disc 106. In other words, a magnetic force B for mounting and driving acts substantially perpendicularly to the rotation axis A. It can also be stated that the shutter disc 106 has a principal extension plane E (xy-plane in FIGS. 2 and 3) arranged substantially perpendicularly to the rotation axis A, and that the applied magnetic force B for driving and mounting the disc 106 acts substantially parallel to the principal extension plane E.

Although not shown in the figures, the magnetic force B comprises in addition to said predominant radial force component also a small axial force component acting parallel to the rotation axis A to compensate external forces such as a gravitational force acting on the shutter disc 106. In other words, the applied magnetic force B has—although not shown in the figures—a small component in the z-direction that overcomes the gravitational force on the shutter disc 106 to allow the shutter disc 106 to become suspended. The magnitude of the magnetic force B is greater, in particular significantly greater, than the magnitude of the gravitational force acting on the shutter disc 106. Just as an example, a weight of the shutter disc 106 may be between 50 g and 1 kg, preferentially between 50 g and 500 g, more preferentially between 50 g and 300 g. Further, a magnitude of the magnetic force B may be between 0.1 N and 5 N per magnet coil 118. However, other values for the magnetic force B can also be applied.

Note that in FIG. 2 a state is shown in which the shutter disc 106 is arranged on the very same height (with respect to the z-direction) as the stator 112 with the magnet coils 118. When the shutter disc 106 is moved slightly in negative z-direction due to gravity (not shown in FIG. 2), the arrow denoting the magnetic force B will also point slightly in the negative z-direction such that the shutter disc 106 is slightly lifted again in the positive z-direction by the magnetic force B.

Furthermore, the magnet coils 118 are supplied with current in a controlled manner such that at a moment in time each magnet coil 118 exerts either an attractive force or a repulsive force on the shutter disk 106. In particular, when a specific magnet 116 of the shutter disk 106 approaches a specific magnet coil 118 of the stator 112, this magnet coil 118 exerts an attractive force on the respective magnet 116. Further, when a specific magnet 116 of the shutter disk 106 moves away from a specific magnet coil 118 of the stator 112, this magnet coil 118 exerts a repulsive force on the respective magnet 116. Furthermore, also positioning of the shutter disc 106 is based on controlling the magnet coils 118 such that they generate either attractive or repulsive forces as required for a specific desired position.

By virtue of this arrangement and configuration of the drive and mounting device 110 and this arrangement of the applied magnetic force B, a rotation of the shutter disc 106 and a positionally accurate mounting of the shutter disc 106 can easily be realized with the aid of the magnetic drive and mounting device 110. In particular, an x-position Px and a y-position Py of the shutter disc 106 can be set highly accurately and vibrations of the shutter disc 106 can thus be reduced. In this case, the x-position Px is a position with respect to a first direction x (x-direction) arranged perpendicular to the rotation axis A, and the y-position Py is a position with respect to a second direction y (y-direction) arranged perpendicular to the first direction and to the rotation axis.

For example, the magnet coils 118 each have a wire winding 121 with a wire 123 (e.g., copper wire). The wire 123 is sheathed with an insulating material 125, for example. The insulating material 125 can comprise, for example, polytetrafluoroethylene, polyether ether ketone and/or a polyimide.

As can be seen in FIG. 3, the at least one opening 108 (three openings 108 in the example shown) of the shutter disc 106 is embodied as at least one indentation 122 on an outer edge 124 of the shutter disc 106.

The shutter disc 106 with the plurality of (e.g., three) openings 108 has a respective shielding region 126 between each two adjacent openings from among the plurality of openings 108 along the circumferential line U. In the example in FIG. 3, the shutter disc thus has three openings 108 and three shielding regions 126. The shielding regions 126 each serve for shielding the operating light 16 (FIG. 2). The shielding regions 126 each have rounded corners 128 as viewed in a plan view parallel to the rotation axis A (i.e., in the view from FIG. 3). This has the advantage over non-rounded corners that material of the shutter disc 106 is saved and a mass of the shutter disc 106 is thus kept as small as possible.

In FIG. 3, a beam cross-section shape 130 of the operating light 16 at the location of the shutter disc 106 is shown using dashed lines. Moreover, a tolerance region 132 arranged uniformly around the beam cross-section shape 130 is depicted. In the example shown, the beam cross-section shape 130 is circular and the tolerance region 132 is formed ring-shapedly around the beam cross-section shape 130. In other examples, however, the beam cross-section shape 130 and accordingly also the tolerance region 132 can also have a different shape.

By way of example, the shutter disc 106 is configured in such a way that its respective shielding regions 126 shield only the beam cross-section shape 130 together with the tolerance region 132, as viewed in the plan view parallel to the rotation axis A (i.e., in the view from FIG. 3). In particular, a region outside the beam cross-section shape 130 together with the tolerance region 132 of the operating light 16 is not shielded by the shielding region of the shutter disc 106. This, too, serves to save material of the shutter disc 106 and to keep the mass of the shutter disc 106 as small as possible. This is because a small mass of the shutter disc 106 means that a low rotational energy is necessary to rotationally drive the shutter disc 106. Since the drive and mounting device 110 thus needs only to provide a low rotational energy, the drive and mounting device 110 can be of even more compact and simpler design. A further advantage of a smaller mass of the shutter disc 106 is that in the case of failure of the drive and mounting device 110, a placement bearing (not shown)—also called emergency bearing or catching bearing—is subjected to less loading.

As can be seen in FIG. 3, the magnet coils 118 arranged on the stator 112 can each have an iron core 134, whereby a magnetic flux can be improved. Alternatively—i.e., instead of an iron core 134—the magnet coils 118 can each have a non-ferromagnetic core (not shown) or a plastic core 136. A plastic core 136 enables remagnetization losses to be reduced. For reasons of clarity, only some of the cores 134, 136 are provided with a corresponding reference sign.

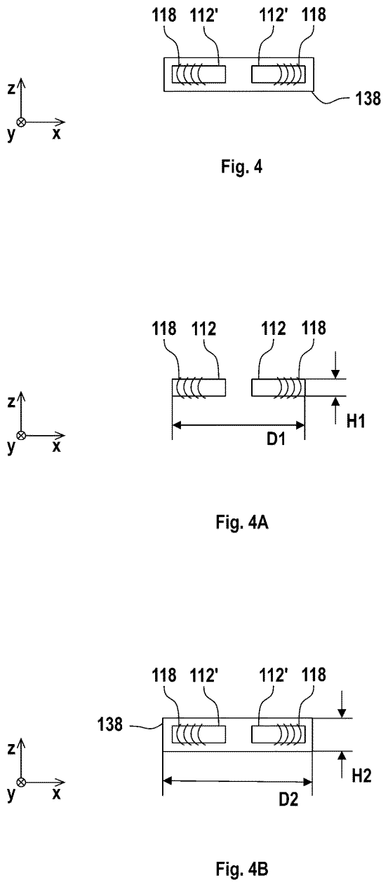

As illustrated in FIG. 4, the magnet coils 118 of the stator 112′ can be sheathed with a plastic material 138. Outgassing into the vacuum V can thus be reduced or avoided. The plastic sheathing 138 can be arranged in particular in addition to the wire insulation 125 (FIG. 2).

The plastic sheathing 138 can also be made significantly thinner than is shown in FIG. 4. By way of example, the plastic sheathing 138 is made so thin that a gap (similar to the gap 119 in FIG. 2) between the magnets 116 and the magnet coils 118 with the plastic sheathing 138 has a gap width (similar to the gap width C in FIG. 2) which is 0.5 mm or less, 0.3 mm or less and/or 0.2 mm or less.

The sheathing with the plastic material 138 is produced, for example, in a first step by movement (e.g., immersion) of the stator 112′ with the magnet coils 118 arranged thereon into a liquid and/or viscous plastic material (e.g., epoxy resin, PUR, etc.). The liquid and/or viscous plastic material is provided, e.g., in a shaping container. The container comprises, e.g., an insulator material, plastic, aluminium and/or titanium. The container does not comprise iron, for example. The liquid and/or viscous plastic material is cured in a second step. A cover plate can optionally be arranged on the cured plastic material. In a third step, the shaping container is removed. The steps described take place under a vacuum atmosphere, for example.

FIG. 4A and FIG. 4B illustrate dimensions of the stator 112, 112′ with the magnet coils 118—in one instance without the plastic sheathing 138 (FIG. 4A) and in one instance with the plastic sheathing 138 (FIG. 4B). As can be seen in FIG. 4A, the stator 112 has a diameter D1 and a height H1. The height H1 relates, for example, to a direction z arranged perpendicular to the diameter D1. For example, the diameter D1 is 100 mm or less, 80 mm or less, 50 mm or less, 30 mm or less and/or 10 mm or less. Additionally or instead, the height H1 is, for example, 100 mm or less, 80 mm or less, 50 mm or less, 30 mm or less and/or 10 mm or less. FIG. 4B shows the dimensions of the stator 112′ with the plastic sheathing 138 (FIG. 4A), where H2 is a corresponding height of the stator 112′ and D2 is a corresponding diameter of the stator 112′.

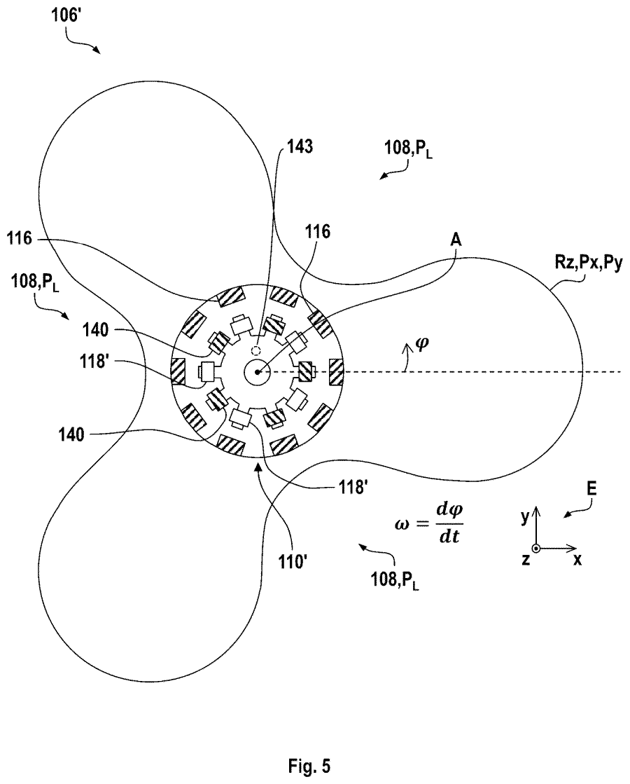

As shown in FIG. 5, the magnetic drive and mounting device 110′ can have a plurality of sensor units 140 for detecting a position Rz, Px, Py of the shutter disc 106. The position Rz, Px, Py can be detected, e.g., by detecting an offset in the x-direction and the y-direction of the rotation axis A relative to the shutter disc 106. For reasons of clarity, only some of the sensor units 140 are provided with a reference sign in the figures. The sensor units 140 can be configured, e.g., in each case as eddy current sensors, capacitive sensors and/or inductive sensors. With the aid of the sensor units 140, it is possible to detect a rotational position Rz of the shutter disc 106 with respect to the rotation about the rotation axis A. It is thus possible, for example, also to detect and/or determine a rotation angle φ of the shutter disc 106, a position P_{L} of a respective opening 108 of the shutter disc 106 and/or an angular frequency ω=dφ/dt of the shutter disc 106. An x-position and a y-position of the disc 106 can additionally be detected with the aid of the sensor units 140.

The sensor units 140 can be arranged, e.g., alternately with the magnet coils 118′ along the third circumferential line around the rotation axis A.

In the embodiment in FIG. 5, the magnet coils 118′ for driving the disc 106 and the sensor units 140 for detecting a position Rz, Px, Py of the disc 106 are mutually different units.

As an alternative thereto, it is also possible for the magnet coils 118 (FIG. 3), for example, also to be configured in each case as actuator coils for magnetically driving the shutter disc 106 and as sensor units 140′for detecting a position Rz, Px, Py of the shutter disc 106. Using the magnet coils 118 as sensor units 140′for detecting a position Rz, Px, Py of the shutter disc 106 may be based on detecting a magnetic induction in the magnet coils 118 induced by the magnets 116. In particular, when a specific magnet 116 moves by a specific magnet coil 118, a small inductive voltage may be induced at the specific magnet coil 118 which provides a positional information of this magnet coil 118. By measuring the inductive voltages at the magnetic coils 118 induced by the magnets 116 moving by, the position Rz, Px, Py of the shutter disc 106 can be determined.

The shutter apparatus 100 can have a closed-loop control device 142 for controlling a magnetic drive of the shutter disc 106 and a magnetic mounting of the shutter disc 106. The closed-loop control device 142 is, e.g., part of the computing device 104 (FIG. 2). The closed-loop control device 142 is configured in particular for controlling the magnetic drive of the shutter disc 106 and the magnetic mounting of the shutter disc 106 in a feedback closed-loop control on the basis of detected sensor data S_{A} of a position Rz, Px, Py of the shutter disc 106. The sensor data S_{A} are, for example, detected by the sensor units 140, 140′ (FIGS. 3, 5) and communicated to the closed-loop control device 142.

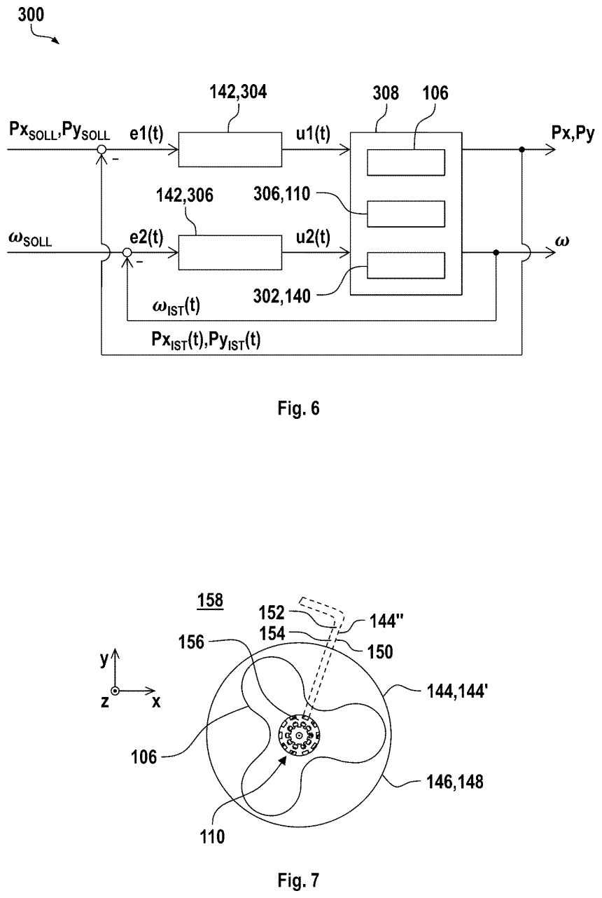

FIG. 6 shows an exemplary closed-loop control circuit 300 for controlling the magnetic drive of the shutter disc 106 and the magnetic mounting of the shutter disc 106.

The closed-loop control circuit 300 serves for controlling the angular frequency ω (e.g., also the rotational speed) of the shutter disc 106 and for controlling the x-position Px and the y-position Py of the shutter disc 106. The closed-loop control circuit 300 can optionally also serve for controlling the rotational position Rz if angular frequency is set to ω. In this case, the degrees of freedom Rx, Ry and Pz are still passively stabilized.

In particular, an actual angular frequency ω_{IST}(t) of the shutter disc 106 is detected by use of a sensor system 302 (e.g., the sensor units 140), fed in negative form to a first comparison unit, and compared with a predetermined setpoint angular frequency ω_{SOLL}, and a first deviation e1(t) is determined and fed to a first controller unit 304 and a first manipulated value u1(t) is determined by use of the first controller unit 304. An actuator system 306 (drive and mounting device 110) is then controlled on the basis of the first manipulated value u1(t) in order to control the angular frequency w of the shutter disc 106 to the predetermined setpoint angular frequency ω_{SOLL}.

Moreover, an actual position Px_{IST}(t), Py_{IST}(t) of the shutter disc 106 is detected by use of the sensor system 302 (e.g., the sensor units 140), fed in negative form to a second comparison unit, and compared with a corresponding predetermined setpoint position Px_{SOLL}, Py_{SOLL}, and a second deviation e2(t) is determined and fed to a second controller unit 306 and a second manipulated value u2(t) is determined by use of the second controller unit 306. The actuator system 306 (drive and mounting device 110) is then controlled on the basis of the second manipulated value u2(t) in order to control the position Px, Py of the shutter disc 106 to the predetermined setpoint position Px_{SOLL}, Py_{SOLL}.

The reference sign 308 in FIG. 6 denotes a controlled system of the closed-loop control circuit 300, comprising the shutter disc 106, the sensor system 302 (e.g., the sensor units 140) and the actuator system 306 (the drive and mounting device 110). The first and second controller units 304, 306 are in particular part of the closed-loop control device 142 (FIG. 2).

With the aid of the closed-loop control device 142, it is thus possible to accurately control the angular frequency ω (rotational speed) of the shutter disc 106 and the position Rz, Px, Py of the shutter disc 106 with respect to the three degrees of freedom Rz, Px, Py (i.e., a rotation about the z-direction, a translation in the x-direction and a translation in the y-direction). In this case, the remaining three degrees of freedom (i.e., a rotation about the x-direction, a rotation about the y-direction and a translation in the z-direction) are automatically passively stabilized.

The closed-loop control device 142 can also be configured to automatically balance the shutter disc 106 by controlling the x-position Px and the y-position Py of the shutter disc 106.

Moreover, at least one acceleration sensor 143 (e.g., on the stator 112) can be provided, as shown by way of example in FIG. 5. In this case, the closed-loop control device 142 can be configured to balance the shutter disc 106 on the basis of detected data of the at least one acceleration sensor 143.

As shown in FIG. 7, the shutter apparatus 100 can optionally have a cooling apparatus 144, 144′, 144″ for cooling the magnetic drive and mounting device 110.

In a first variant, the cooling apparatus 144 has a cooling ring 146 arranged around the shutter disc 106 and serving for dissipating heat.

In a second variant, the cooling apparatus 144′ has a (e.g., closed) cooling housing 148 arranged around the shutter disc 106 and serving for dissipating heat. In FIG. 7, for illustration reasons, the cooling housing 148 cannot be seen in a closed state.

In a third variant, the cooling apparatus 144″ has—in addition to or instead of the cooling ring 146 or the cooling housing 148—a cooling pipe 150 with a capillary structure 152 and a working liquid 154 (e.g., alcohol or some other suitable liquid) accommodated in the interior of the cooling pipe 150. The cooling pipe 150 connects a space 156 around the shutter disc 106 or a space 156 around the drive and mounting device 110 to an exterior space 158.

In some implementations, the operations associated with processing of data described in this document (e.g., for closed-loop control, for determining the control signals for the stator magnet coils based on the signal from the sensors and the intended positions and/or movements of the shutter disc) can be performed by one or more programmable processors executing one or more computer programs to perform the functions described in this document. A computer program can be written in any form of programming language, including compiled or interpreted languages, and it can be deployed in any form, including as a stand-alone program or as a module, component, subroutine, or other unit suitable for use in a computing environment.

For example, the computing device 104 can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of the computing device 104 can include one or more processors for executing instructions and one or more storage area devices for storing instructions and data. Generally, the computer device 104 will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, and flash storage devices; magnetic disks, e.g., internal hard disks or removable disks; magneto-optical disks; and CD-ROM, DVD-ROM, and/or Blu-ray discs.

In some implementations, the processes that involve processing of data can be implemented using software for execution on one or more mobile computing devices, one or more local computing devices, and/or one or more remote computing devices.

For instance, the software forms procedures in one or more computer programs that execute on one or more programmed or programmable computer systems, either in the mobile computing devices, local computing devices, or remote computing systems (which may be of various architectures such as distributed, client/server, or grid), each including at least one processor, at least one data storage system (including volatile and non-volatile memory and/or storage elements), at least one wired or wireless input device or port, and at least one wired or wireless output device or port.

In some implementations, the software may be provided on a medium, such as a CD-ROM, DVD-ROM, Blu-ray disc, solid state drive, or hard disk drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Although the present invention has been described on the basis of exemplary embodiments, it is modifiable in diverse ways. For example, for application in the UV (e.g., between 100 nm to 400 nm) including DUV (between 30 nm and 250 nm) the opening 108 of the shutter disk 106 may be filled with a transparent material being transparent in the respective wavelength regime.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
24 Camera device
100 Shutter apparatus
102 Shutter device
104 Computing device
106 Shutter disc
108 Opening
110, 110′ Drive and mounting device
112, 112′ Stator
114 Inner edge
116 Magnet
118, 118′ Magnet coil
119 Gap
120 Cutout
121 Wire winding
122 Indentation
123 Wire
124 Outer edge
125 Insulating material
126 Shielding region
128 Rounded corner
130 Beam cross-section shape
132 Tolerance region
134 Iron core
136 Plastic core
138 Plastic material
140, 140′ Sensor unit
142 Closed-loop control device
143 Acceleration sensor
144, 144′, 144″ Cooling apparatus
146 Cooling ring
148 Cooling housing
150 Cooling pipe
152 Capillary structure
154 Working liquid
156 Space
158 Exterior space
200 Vacuum housing
300 Closed-loop control circuit
302 Sensor system
304 Controller unit
306 Controller unit
308 Controlled system
A Rotations axis
B Magnetic force
C Gap width
D1, D2 Diameter
E Principal extension plane
e1 Deviation
e2 Deviation
4 Rotation angle
H1, H2 Height
M1-M6 Mirrors
ω Angular frequency
ω_{IST} Angular frequency
ω_{SOLL} Angular frequency
Px, Py Position
Px_{IST}, Py_{IST} Position
Px_{SOLL}, Py_{SOLL} Setpoint position
R Direction
Rz Rotational position
S_{A} Sensor data
S_{B} Control signal
S_{C} Control signal
U Circumferential line
u1 Manipulated value
u2 Manipulated value
V Vacuum

What is claimed is:

1. A shutter apparatus for a lithography apparatus and/or mask test apparatus, having
a shutter disc mounted rotatably about a rotation axis with at least one opening spaced apart from the rotation axis and serving for transmitting operating light of the lithography apparatus and/or the mask test apparatus, and
a magnetic drive and mounting device, with the aid of which the shutter disc is mounted rotatably about the rotation axis and which is configured for rotationally driving the shutter disc about the rotation axis, wherein the shutter disc and the drive and mounting device are configured to be arranged within a vacuum housing of the lithography apparatus and/or the mask test apparatus.

2. The shutter apparatus of claim 1, wherein the magnetic drive and mounting device is configured to magnetically mount and drive the shutter disc by use of a magnetic force acting substantially radially on the shutter disc.

3. The shutter apparatus of claim 1, wherein the magnetic drive and mounting device has a plurality of magnets provided on an inner edge of the shutter disc and a plurality of magnet coils spaced apart from the shutter disc with the magnets, and the magnets and the magnet coils are configured to cooperate in order to provide a magnetic mounting and a magnetic drive of the shutter disc.

4. The shutter apparatus of claim 1, wherein the shutter disc forms a rotor of the drive and mounting device, the shutter disc has a central cutout having the rotation axis, and the magnetic drive and mounting device has a stator spaced apart from the shutter disc and arranged within the central cutout.

5. The shutter apparatus of claim 4, wherein
the stator has a diameter that is 100 mm or less, 80 mm or less, 50 mm or less, 30 mm or less and/or 10 mm or less, and/or
the stator has a height that is 100 mm or less, 80 mm or less, 50 mm or less, 30 mm or less and/or 10 mm or less.

6. The shutter apparatus of claim 1, wherein
the magnetic drive and mounting device has a plurality of sensor units for detecting a position of the shutter disc, and/or
the magnetic drive and mounting device has a plurality of sensor units for detecting a rotational position of the shutter disc with respect to a rotation about the rotation axis, an x-position with respect to a first direction (x) arranged perpendicular to the rotation axis, and/or a y-position with respect to a second direction (y) arranged perpendicular to the first direction and to the rotation axis.

7. The shutter apparatus of claim 1, wherein the magnetic drive and mounting device has a plurality of magnet coils configured to cooperate with magnets on the shutter disc for the magnetic mounting and for the magnetic drive of the shutter disc, and wherein the plurality of magnet coils are each configured as a sensor unit for detecting a position of the shutter disc.

8. The shutter apparatus of claim 1, having a closed-loop control device for controlling, on the basis of detected sensor data of a position of the shutter disc, a magnetic drive of the shutter disc and/or a magnetic mounting of the shutter disc in such a way as to control an angular frequency of the shutter disc with respect to a rotation about the rotation axis, to control an x-position of the shutter disc in a first direction (x) perpendicular to the rotation axis, and/or to control a y-position of the shutter disc in a second direction (y) perpendicular to the first direction (x) and to the rotation axis.

9. The shutter apparatus of claim 8, wherein the closed-loop control device is configured to automatically balance the shutter disc by controlling the x-position and the y-position of the shutter disc.

10. The shutter apparatus of claim 9, wherein the magnetic drive and mounting device has at least one acceleration sensor, and the closed-loop control device is configured to balance the shutter disc on the basis of detected data of the at least one acceleration sensor.

11. The shutter apparatus of claim 1, wherein
the at least one opening of the shutter disc is embodied as at least one indentation on an outer edge of the shutter disc.

12. The shutter apparatus of claim 1, wherein
the shutter disc has a plurality of the openings along a circumferential line around the rotation axis and a shielding region of the shutter disc for shielding the operating light is arranged between each two adjacent openings from among the plurality of openings along the circumferential line, and
the shielding region has a rounded corner as viewed in a plan view parallel to the rotation axis, and/or
the operating light has a beam cross-section shape at the location of the shutter disc and a shape of the respective shielding region as viewed in a plan view parallel to the rotation axis is embodied in such a way that the respective shielding region shields the beam cross-section shape and a tolerance region around the beam cross-section shape.

13. The shutter apparatus of claim 1, wherein
the magnetic drive and mounting device has a plurality of magnet coils configured to cooperate with magnets on the shutter disc for the magnetic mounting and for the magnetic drive of the shutter disc, and
the magnet coils each have a metal core, or
the magnet coils each have a plastic core.

14. The shutter apparatus of claim 1, wherein
the magnetic drive and mounting device has a plurality of magnet coils configured to cooperate with magnets on the shutter disc for the magnetic mounting and for the magnetic drive of the shutter disc,
the magnet coils each have a wire winding with a wire sheathed with an insulating material, and
the insulating material comprises polytetrafluoroethylene, polyether ether ketone and/or a polyimide.

15. The shutter apparatus of claim 1, wherein
the magnetic drive and mounting device has a plurality of magnet coils configured to cooperate with magnets on the shutter disc for the magnetic mounting and for the magnetic drive of the shutter disc, and
the magnet coils are sheathed with a plastic material.

16. The shutter apparatus of claim 1, having a cooling apparatus for cooling the magnetic drive and mounting device, wherein the cooling apparatus has:
a cooling ring arranged around the shutter disc and serving for dissipating heat, and/or
a cooling housing arranged around the shutter disc and serving for dissipating heat, and/or
a cooling pipe with a capillary structure and a working liquid accommodated in the interior of the cooling pipe, wherein the cooling pipe connects a space around the shutter disc to an exterior space.

17. A lithography apparatus and/or mask test apparatus comprising a shutter apparatus of claim 1 and comprising a vacuum housing for providing a vacuum, wherein the shutter disc and the drive and mounting device of the shutter apparatus are arranged within the vacuum housing.

18. The lithography apparatus of claim 17, wherein the magnetic drive and mounting device is configured to magnetically mount and drive the shutter disc by use of a magnetic force acting substantially radially on the shutter disc.

19. The lithography apparatus of claim 17, wherein the magnetic drive and mounting device has a plurality of magnets provided on an inner edge of the shutter disc and a plurality of magnet coils spaced apart from the shutter disc with the magnets, and the magnets and the magnet coils are configured to cooperate in order to provide a magnetic mounting and a magnetic drive of the shutter disc.

20. The lithography apparatus of claim 17, wherein the shutter disc forms a rotor of the drive and mounting device, the shutter disc has a central cutout having the rotation axis, and the magnetic drive and mounting device has a stator spaced apart from the shutter disc and arranged within the central cutout.
